(19) United States
(12) Patent Application Publication
(10) Pub. No.: US 2022/0055853 A1
(43) Pub. Date: Feb. 24, 2022

(54) APPLICATION AND FASTENING OF A DEFINED NUMBER OF INDIVIDUAL ELEMENTS TO A SUBSTRATE WEB

(71) Applicant: GIESECKE+DEVRIENT CURRENCY TECHNOLOGY GMBH, Munchen (DE)

(72) Inventors: Mario KELLER, Seebruck (DE); Maik Rudolf Johann SCHERER, Grainau (DE); Michael RAHM, Bad Tolz (DE)

(21) Appl. No.: 17/299,104

(22) PCT Filed: Nov. 29, 2019
(86) PCT No.: PCT/EP2019/000327

§ 371 Date: Jun. 2, 2021

(30) Foreign Application Priority Data
Dec. 3, 2018 (DE) 10 2018 009 472.4

(51) Int. Cl. B65H 37/04

(52) U.S. Cl. CPC B65H 37/04; B65H 2301/5113; B65H 2301/441; B65H 2301/5115

(57) ABSTRACT

The invention relates to a method for applying and attaching a defined number n of individual elements to a defined number m of predefined positions on a surface of a moving substrate web. The invention further relates to a moving substrate web onto which a defined number n of individual elements are to be applied and attached to a defined number m of predefined positions on a surface of a moving substrate web. According to the invention, an adhesive is applied to the surface of the substrate web at each of the predefined positions so that respectively at least one individual element can be attached at respectively one predefined position, and no adhesive is applied outside the predefined positions.

The invention relates to a method for applying and attaching a defined number n of individual elements to a defined number m of predefined positions on a surface of a moving substrate web. The invention further relates to a moving substrate web onto which a defined number n of individual elements are to be applied and attached to a defined number m of predefined positions on a surface of a moving substrate web.

For this, a so-called “Fluid self-assembly process” is known from WO 03/0548808 A2, U.S. Pat. No. 6,417,025 or WO 01/33621 A2, for example, in which integrated circuits, so-called chips, are “flushed” or washed into recesses of a foil. For example, a carrier foil in endless form is furnished with recesses which have approximately the size of the chip to be deposited. The recesses are distributed over the endless foil in such a way that the desired number of chips will be contained in the security element when the foil is divided into individual security elements later. In the next step, a liquid containing the chips is poured over the such prepared foil. In doing so, the chips are washed into the recesses and align themselves in this way.

Furthermore, the so-called “pick-and-place” method is known from the prior art, in which a gripper arm takes an individual element out from a storage container and positions it at a desired location on a substrate web and attaches it there. However, this method has the disadvantage that it is very slow and therefore cannot apply a large number of individual elements to the substrate web in a short time.

The invention is therefore based on the object of developing a generic method and a generic moving substrate web in such a way that the disadvantages of the prior art are eliminated.

This object is achieved by the features of the independent claims. Developments of the invention are subject matter of the dependent claims.

According to the invention, the method comprises the following steps:
a) supplying the substrate web,
b) applying an adhesive to the surface of the substrate web at each of the predefined positions so that respectively at least one individual element can be attached at respectively one predefined position and no individual element can be attached outside the predefined positions,
c) feeding a number n1 of individual elements onto the surface of the substrate web, the number n1 being greater than or equal to the number n, the individual elements, which come into contact with adhesive with one of the predefined positions, being attached at this predefined position by the adhesive,
d) removing the individual elements which do not adhere to one of the predefined positions with adhesive from the surface of the substrate web.

In the moving substrate web according to the invention, an adhesive is applied to the surface of the substrate web at each of the predefined positions, so that respectively at least one individual element can be attached at respectively one predefined position, and no adhesive is applied outside the predefined positions.

The term “individual element” here refers to electrical or electronic structural elements or structural parts such as for example microprocessors with or without integrated antennas, LEDs, sensors, batteries, solar cells, resistors, capacitors, transistors or the like. It additionally also comprises optical elements such as lenses, Fresnel lenses or polarizers as well as security elements for security documents.

At least one individual element means that one individual element or several individual elements can be attached at a predefined position. If an individual element is to be attached at a predefined position, the area of the adhesive applied to the surface of the substrate web is at most as large as the area of the individual element. If, however, several individual elements are to be attached at a predefined position, the area of the adhesive applied to the surface of the substrate web is larger than the area of an individual element, preferably as large as the sum of the areas of the individual elements to be attached.

As a “substrate web” rolled goods in the form of paper, plastic, glass or textile and any kind of composite material, for example carbon fibre reinforced materials, come into consideration. The same materials can also be present and processed in sheet form, in the form of sheets, plates or formatted goods. The web width can be 1 m or more, for example, the web speed of a moving substrate web is usually at least 1 m/min. The surface of the moving substrate web is here the front and/or rear side of the substrate web and in particular not the side areas thereof, since the area of the side areas is negligibly small in relation to the area of the front or rear side.

Predefined positions on a surface of a moving substrate path are predefined and fixed by a user, so they are not stochastically or randomly arranged. Preferably, the predefined positions are arranged in a grid-like manner or regularly in columns and rows on the surface of the substrate web, the columns and rows respectively having a predefined distance from one another. Of course, an arrangement with a predefined shift between the rows and/or columns is also possible, or the rows and/or columns can be arranged in the form of curved or serrated lines.

As an adhesive there can be used any adhesives or glues known in the prior art which attach an individual element to the substrate web in such a way that the individual element immediately adheres to the substrate web without being detached from the substrate web when the substrate web is moved.

Applications of the elements placed according to the invention relate to, for example, security documents such as bank notes or ID cards having chips or also packaging material, labels or other two-dimensional products. In this regard, for example, optical elements can be employed to increase the visual attractiveness. In another example, chips are used to process, store and output data, for example for authentication purposes. Further, other functionalities such as sensors are also conceivable.

According to a further advantageous configuration, it is provided that the substrate web, after it has been furnished with the individual elements, is cut into individual copies. Such copies are, for example, the mentioned security documents.

According to a preferred embodiment, it is provided that the number n of individual elements is equal to the number m of predefined positions. Here, the method step c) is carried out until at all of the predefined positions respectively one individual element is located. Thus, after the completion of the method, at each predefined position exactly one individual element is located.

According to a further advantageous configuration, it is provided that in step c) the feeding of the number n1 of individual elements onto the surface of the substrate web is effected by heaping up and/or washing and/or spraying and/or blowing the individual elements onto the surface of the substrate web. In addition, the substrate web can also be vibrated or shaken so that individual elements in the vicinity of predefined positions that are still free are moved towards these.

According to a further advantageous embodiment, it is provided that in step d) the removal of the individual elements which do not adhere with adhesive to one of the predefined positions from the surface of the substrate web is effected by scraping off and/or blowing off and/or sucking off and/or dropping these individual elements from the surface of the substrate web. Excess individual elements that cannot be assigned to a free predefined position are thus removed from the substrate web.

According to a further advantageous embodiment, it is provided that at at least one, preferably at all, of the predefined positions on the surface of the moving substrate web, a recess is incorporated in the surface of the moving substrate web, the area of the respective recess being so large that respectively one individual element can be incorporated into respectively one recess. In the recesses there is the adhesive which attaches the individual elements in the recess. This has the particular advantage that when excess individual elements are removed, for example by scraping or wiping off, the already adhering individual elements are not torn off the substrate web. The recess, in an additional function, can also serve for aligning the individual element relative to the substrate web.

According to a further advantageous configuration, it is provided that at least one opening is incorporated in the surface of the moving substrate web at at least one, preferably at all, of the predefined positions on the surface of the moving substrate web. The area of the respective opening is so small that no individual element fits through and thus does not slip through the opening. The individual elements are sucked to the predefined positions by a negative pressure in the openings. The negative pressure is particularly preferably exerted to the surface of the substrate web which is opposite to the surface of the substrate web to which the individual elements are applied. This supports the feeding of the individual elements to the predefined positions on the substrate web in a particularly advantageous way. Instead of a through opening in the substrate web, the latter can also be modified at the predefined positions to the effect that it has increased porosity there. As a result, the exerted negative pressure will have a stronger effect on the predefined porous locations than on the rest of the surface of the substrate web and will lead to an advantageous positioning of the individual elements only there.

After step d), the individual elements located at the predefined positions can be encapsulated for special protection. The encapsulation can consist of an areal or partial lamination or a lacquer encapsulation.

It will be appreciated that the features mentioned hereinabove and those to be explained hereinafter are employable not only in the stated combinations but also in other combinations without going beyond the framework of the present invention, provided this is covered by the scope of protection of the claims.

With reference to the following embodiment example and the complementary FIGURE, the advantages of the invention will be explained. The embodiment example represents a preferred embodiment, without the invention being in any way limited thereto. Furthermore, the representation in the FIGURE is strongly schematic for the sake of better comprehension and does not reflect the actual conditions. In particular, the proportions shown in the FIGURE do not correspond to the relations existing in reality and serve exclusively to improve the clearness. Furthermore, the embodiment described in the following embodiment example is reduced to the essential core information for the sake of easier comprehension. In the practical implementation, substantially more complex patterns or images can be used.

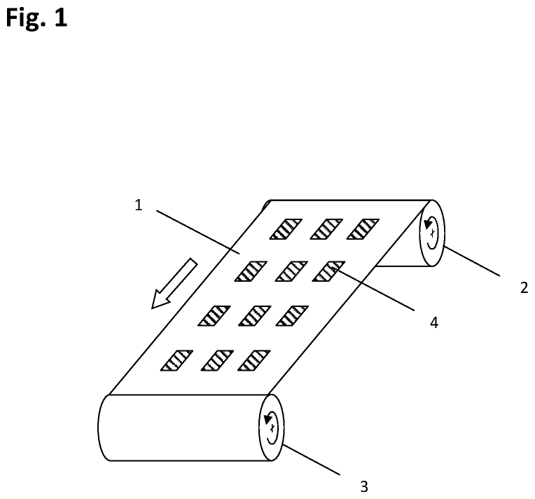

The single FIG. 1 shows a substrate web 1 which is wound on a roll 2. The substrate web 1 is unwound from the roll 2 in the direction of the arrow and then rewound onto a roll 3. On the surface of the substrate web 1 there are predefined positions 4. In FIG. 1, m=12 predefined positions 4 are represented, further ones are located on the substrate web 1 still wound on the roll 2 or on the substrate web 1 already rewound on the roll 3.

Each of these positions 4 is furnished with an adhesive so that respectively at least one individual element can be applied to them with a method not represented in FIG. 1 between unwinding from roll 2 and rewinding onto roll 3.

1.-13. (canceled)

14. A method for applying and attaching a defined number n of individual elements to a defined number m of predefined positions on a surface of a moving substrate web, characterized by the following steps:
a) supplying the substrate web,
b) applying an adhesive to the surface of the substrate web at each of the predefined positions so that respectively at least one individual element can be attached at respectively one predefined position and no individual element can be attached outside the predefined positions,
c) feeding a number n1 of individual elements onto the surface of the substrate web, the number n1 being greater than or equal to the number n, the individual elements, which come into contact with adhesive with one of the predefined positions, being attached at this predefined position by the adhesive,
d) removing the individual elements which do not adhere to one of the predefined positions with adhesive from the surface of the substrate web.

15. The method according to claim 14, wherein the number n of individual elements is equal to the number m of predefined positions and step c) is carried out until there is located respectively one individual element at all of the predefined positions.

16. The method according to claim 14, wherein in step c) the feeding of the number n1 of individual elements onto the surface of the substrate web is effected by heaping up and/or washing and/or spraying and/or blowing the individual elements onto the surface of the substrate web.

17. The method according to claim 16, wherein the substrate web is vibrated or shaken.

18. The method according to claim 14, wherein in step d) the removal of the individual elements which do not adhere with adhesive to one of the predefined positions from the surface of the substrate web is effected by scraping off and/or blowing off and/or sucking off and/or dropping these individual elements from the surface of the substrate web.

19. The method according to claim 14, wherein at at least one, preferably at all, of the predefined positions on the surface of the moving substrate web a recess is incorporated in the surface of the moving substrate web, the area of the respective recess being so large that respectively at least one individual element can be incorporated into respectively one recess.

20. The method according to claim 14, wherein at at least one, preferably at all, of the predefined positions on the surface of the moving substrate web at least one opening is incorporated into the surface of the moving substrate web or the porosity of the substrate web is increased, the area of the respective opening being so small that no individual element fits through it, and the individual elements are sucked to the predefined positions by a negative pressure in the openings or porous locations.

21. The method according to claim 14, wherein the individual elements on the moving substrate web are encapsulated.

22. The method according to claim 14, wherein the individual elements are electronic or electrical structural parts or structural elements or security elements or optical elements.

23. A moving substrate web to which a defined number n of individual elements are to be applied and attached to a defined number m of predefined positions on a surface of a moving substrate web,
wherein an adhesive is applied to the surface of the substrate web at each of the predefined positions, so that respectively at least one individual element can be attached at respectively one predefined position, and no adhesive is applied outside the predefined positions.

24. The moving substrate web according to claim 23, wherein at at least one, preferably at all, of the predefined positions on the surface of the moving substrate web, a recess is incorporated in the surface of the moving substrate web, the area of the respective recess being so large that respectively at least one individual element can be incorporated into respectively one recess.

25. The moving substrate web according to claim 23, wherein at at least one, preferably at all, of the predefined positions on the surface of the moving substrate web at least one opening is incorporated in the surface of the moving substrate web or the porosity of the substrate web is increased, the area of the respective opening being so small that no individual element fits through it.

26. The moving substrate web according to claim 23, wherein the individual elements are electronic or electrical structural parts or structural elements or security elements or optical elements.
